(19) United States
(12) Patent Application Publication
(10) Pub. No.: US 2025/0298070 A1
(43) Pub. Date: Sep. 25, 2025

(54) DETERMINE GAIN MARGIN FOR A CRYSTAL DRIVER

(71) Applicant: Microchip Technology Incorporated, Chandler, AZ (US)

(72) Inventors: John Charais, Oconomowoc, WI (US); David M. DePaul, Chandler, AZ (US)

(73) Assignee: Microchip Technology Incorporated, Chandler, AZ (US)

(21) Appl. No.: 18/745,685

(22) Filed: Jun. 17, 2024

Related U.S. Application Data
(60) Provisional application No. 63/567,874, filed on Mar. 20, 2024.

(51) Int. Cl. G01R 31/28; G01R 19/10

(52) U.S. Cl. CPC G01R 31/282; G01R 19/10

(57) ABSTRACT

A device having a crystal driver to operate according to a voltage transfer curve and a current reference to provide a current bias to the crystal driver to produce a voltage from the crystal driver within a linear region of the voltage transfer curve of the crystal driver, and to determining a gain margin of the crystal driver based on the measured first voltage on the driver output. A method to force a current bias from a current reference on a driver input, to measure the voltage on the driver output within a linear region of the voltage transfer curve of the crystal driver, and determine a gain margin of the crystal driver based on the measured voltage on the driver output.

### PRIORITY STATEMENT

This application claims priority to U.S. Provisional Patent Application No. 63/567,874, filed Mar. 20, 2024, the contents of which are hereby incorporated in their entirety.

### TECHNICAL FIELD

The present disclosure relates to testing gain margin of a crystal driver, in particular, a current gain margin test mode of a crystal driver.

### BACKGROUND

Crystal oscillator startup issues may include: load capacitors, external crystals, board/package parasitic, and a crystal oscillator driver. Any component or instrument in an external oscillator system can cause a failure in the startup of the oscillator.

The gain of the crystal driver is measured within the linear region of the driver's voltage transfer curve. The linear region of the crystal driver's voltage transfer curve is where the output of the crystal driver changes linearly with respect to the input of the crystal driver. Prior methodologies utilize voltage forcing instruments with higher inaccuracies, which makes it difficult to measure the gain as the instruments may force voltage in the non-linear region of the crystal driver. Instruments with current forcing capabilities of testers have high inaccuracy, which limits the ability to perform a force current measurement operation.

Prior systems utilize voltage forcing instruments to provide measurement bias to short circuit bias point, which is measured to determine where the linear region is centered. Forcing voltage biases (Vbias+nmV, Vbias−nmV) around the bias point (center of the linear region) allows two independent current bias (I2 and I1) to be measured. The instrumentation error of the voltage forcing capability could potentially shift the measurement points outside the linear region, if small enough due to errors. For example, a gain margin measurement via voltage mode has typically been as follows:
a. Measure Vbias, which is the output of the crystal driver when the input is shorted to the output.
b. Force the voltage bias positively around the bias point (Vbias+40 mV) and measure I1 (the input current=6 mA)
c. Force the voltage bias negatively around the bias point (Vbias−40 mV) and measure I2 (the input current=−6 mA)
d. Calculate the gain margin=(I1−I2)/(80 mV)=12 mA/80 mV=0.15
   In this example, the forcing instrument is assumed to have an accuracy of +/−10 mV, so that the worst case for gain margin error due to voltage forcing is (I1−I2)/60 mV=12 mA/60 mV=0.2. Thus, for this example the gain margin error due to forcing is 33%.

External test components or instruments for measuring gain margin of a crystal driver in production may present a point of failure in the startup of the crystal oscillator. Each board is different and multiple testers are used, each with its own accuracy and resolution, which creates a variation in the accuracy of the gain margin testing. In prior systems, a voltage forcing instrument has been used to force voltage. A Vbias has been measured, which was the output of the crystal driver with the input shorted to the output. A first input current (I1) was measured from the voltage forcing instrument where the force was Vbias plus a forced voltage (e.g., +40 mV). A second input current (I2) was measured from a voltage forcing instrument where the force is Vbias minus the forced voltage (e.g., −40 mV). The gain margin is determined as the difference between the first and second input voltages divided by twice the forced voltage (e.g., (I1−I2)/80 mV). Where the forced voltage is subject to instrument variation, small variations in the forced voltage may have significant variation on the determined gain margin.

For an external crystal oscillator, a crystal driver may have a certain gain margin to facilitate startup of the oscillator. Typical testers focus current onto oscillator pins. However, these testers may be limited by the current tester hardware having accuracy issues when forcing current onto specific pins.

Existing gain margin measurement is via voltage mode. Typically, the voltage forcing instrument has an accuracy of +/−10 mV. The voltage forced is kept close to Vbias to stay in the operational range of the crystal driver. The tolerance of the voltage forcing instrument leads to large errors. Also measuring currents accurately on the tester takes a long period of time as integration over a longer period provides higher accuracy. Existing testers do not have high accuracy current forcing capabilities.

There is a need for a method and device to test the gain margin of a crystal driver in production.

### SUMMARY OF THE INVENTION

Aspects provide a method comprising: providing a device comprising: a crystal driver to operate according to a voltage transfer curve and having a driver input, a driver output; and a first current reference to provide a first internal current bias to the driver input to produce a first voltage at the driver output within a linear region of the voltage transfer curve of the crystal driver; forcing a first current bias from the first current bias on the driver input; measuring the first voltage on the driver output; and determining a gain margin of the crystal driver based on the measured first voltage on the oscillator output.

According to an aspect there is provided a method as in the preceding paragraph comprising: simultaneously shorting the driver output to the driver input and forcing a first current bias from the first current bias on the driver input; measuring a second voltage on the driver output; and determining a gain margin of the crystal driver based on the measured first and second voltages on the driver output.

According to an aspect there is provided a method as in the preceding two paragraphs, wherein providing a device comprises: a second current reference to provide a second current bias to the driver input to produce a second voltage at the driver output within a linear region of the voltage transfer curve of the driver circuit; and an input switch to switch between the first current bias and the second current bias; comprising: forcing the second current bias on the driver input; measuring a second voltage on the driver output; and determining a gain margin of the crystal driver based on the measured first and second voltages on the driver output.

According to an aspect there is provided a method as in the preceding three paragraphs wherein providing a device comprises: a programmable current mirror to provide first current bias from the first current reference to the driver input and to provide a second current bias from the first current reference to the driver input, wherein the first and second current biases are to produce a first voltage and a second voltage at the driver output, respectively, that are within the linear region of the voltage transfer curve of the crystal driver; comprising: forcing the second current bias on the driver input; measuring the second voltage on the driver output; and determining a gain margin of the crystal driver based on the measured first and second voltages on the driver output.

According to an aspect there is provided a method as in the preceding four paragraphs, wherein measuring the first voltage on the driver output comprises measuring with an external voltage instrument having an accuracy of +/−100 μV.

According to an aspect there is provided a method as in the preceding five paragraphs, comprising measuring a second voltage on the driver output, wherein determining the gain margin of the crystal driver is based on the measured first and second voltages on the driver output.

According to an aspect there is provided a method as in the preceding six paragraphs, comprising forcing a zero bias current on the driver input; measuring a second voltage on the driver output; and determining a gain margin of the crystal driver by dividing the difference between the first current bias and zero current bias by the difference between the first and second voltages.

According to an aspect there is provided a method as in the preceding seven paragraphs, forcing a second current bias on the driver input; measuring a second voltage on the driver output; and determining a gain margin of the crystal driver by dividing the difference between the first and second current biases by the difference between the first and second voltages.

An aspect provides device comprising: a crystal driver to operate according to a voltage transfer curve and having a driver input, and an driver output; and a first current reference to provide a first current bias to the driver input to produce a first voltage at the driver output within a linear region of the voltage transfer curve of the crystal driver.

According to an aspect there is provided a device as in the preceding paragraph, comprising a feedback switch to short the driver output to the driver input to provide a zero current bias to the driver input when the feedback switch is closed.

According to an aspect there is provided a device as in the preceding two paragraphs, comprising: a second current reference to provide a second current bias to the driver input to produce a second voltage at the driver output within a linear region of the voltage transfer curve of the crystal driver; and an input switch to switch between the first current bias and the second current bias.

According to an aspect there is provided a device as in the preceding three paragraphs, comprising a programmable current mirror to provide the first current bias from the first current reference to the driver input and to provide a second current bias from the first current reference to the driver input, wherein the first and second current biases are to produce the first voltage and a second voltage at the driver output, respectively, that are within a linear region of the voltage transfer curve of the crystal driver.

An aspect provides a system comprising: a device comprising: a crystal driver to operate according to a voltage transfer curve and having a driver input, and a driver output; and a first current reference to provide a first current bias to the driver input to produce a first voltage at the driver output within a linear region of the voltage transfer curve of the crystal driver; a voltage measuring instrument to measure the first voltage on the driver output when the first current bias is forced on the driver input.

According to an aspect there is provided a system as in the preceding paragraph, wherein the device comprises a feedback switch to short the driver output to the driver input to provide a zero current bias to the driver input when the feedback switch is closed to produce a second voltage on the driver output.

According to an aspect there is provided a system as in the preceding two paragraphs, wherein the voltage measuring instrument is to measure the second voltage at the driver output when the zero current bias is provided on the driver input.

According to an aspect there is provided a system as in the preceding three paragraphs, wherein the device comprises: a second current reference to provide a second current bias to the driver input to produce a second voltage at the driver output within a linear region of the voltage transfer curve of the crystal driver; and an input switch to switch between the first current bias and the second current bias.

According to an aspect there is provided a system as in the preceding four paragraphs, wherein the voltage measuring instrument is to measure the second voltage at the driver output when the second current bias is provided to the driver input.

According to an aspect there is provided a system as in the preceding five paragraphs, wherein the device comprises a programmable current mirror to provide the first current bias from the first current reference to the driver input and to provide a second current bias from the first current reference to the driver input, wherein the first and second current biases are to produce the first voltage and a second voltage at the driver output, respectively, that are within a linear region of the voltage transfer curve of the crystal driver.

According to an aspect there is provided a system as in the preceding six paragraphs, wherein the voltage measuring instrument is to measure the second voltage at the driver output when the second current bias is provided to the driver input.

According to an aspect there is provided a system as in the preceding seven paragraphs, wherein the voltage measuring instrument has an accuracy of +/−100 μV.

### BRIEF DESCRIPTION OF THE DRAWINGS

The figures illustrate examples of internal gain margin test mode that may be used to test the gain margin in production and a current mode is used as opposed to a voltage mode.

FIG. 1 shows a block diagram of an internal crystal driver gain margin measurement test circuit having a programmable current mirror.

FIG. 2 shows a block diagram of an internal crystal driver gain margin measurement test circuit to switch between current references.

FIG. 3 shows a block diagram of an internal crystal driver gain margin measurement test circuit having a current reference and a feedback switch.

FIG. 4 shows a block diagram of an internal crystal driver gain margin measurement test circuit with a programmable current mirror.

FIG. 5 shows a block diagram of an internal crystal driver gain margin measurement test circuit with two current references.

FIG. 6 shows a flow chart of a method.

FIG. 7 shows a block diagram of a system.

FIG. 8 shows a block diagram of a device, such as an integrated circuit.

FIG. 9 is a block diagram of circuitry that includes one or more processors operably coupled to one or more data storage devices, wherein the storage includes machine executable code stored thereon and the processors include logic circuitry.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided an internal crystal driver gain margin measurement test circuit that is self-contained and does not rely on the accuracy of an external tester. An internal crystal driver gain measurement test circuit may provide accurate production gain margin measurements and reduce variability of measurements across tester platforms.

An internal crystal driver gain margin measurement test circuit may be used to test the gain margin of the crystal driver in production in a current mode is used as opposed to a voltage mode. The internal crystal driver gain margin measurement test circuit may comprise: (1) a switch to short the input and the output of the crystal driver, (2) an internal current reference, and (3) a programmable current mirror. The gain margin may be measured as: GM=(I1−I2)/(Vbias1−Vbias2), where the two different currents, I1 and I2 may be generated via the internal current reference and the programmable current mirror. With the switch shorting the input and the output of the crystal driver, the output of the crystal driver may be measured while the currents are being forced so as to determine GM.

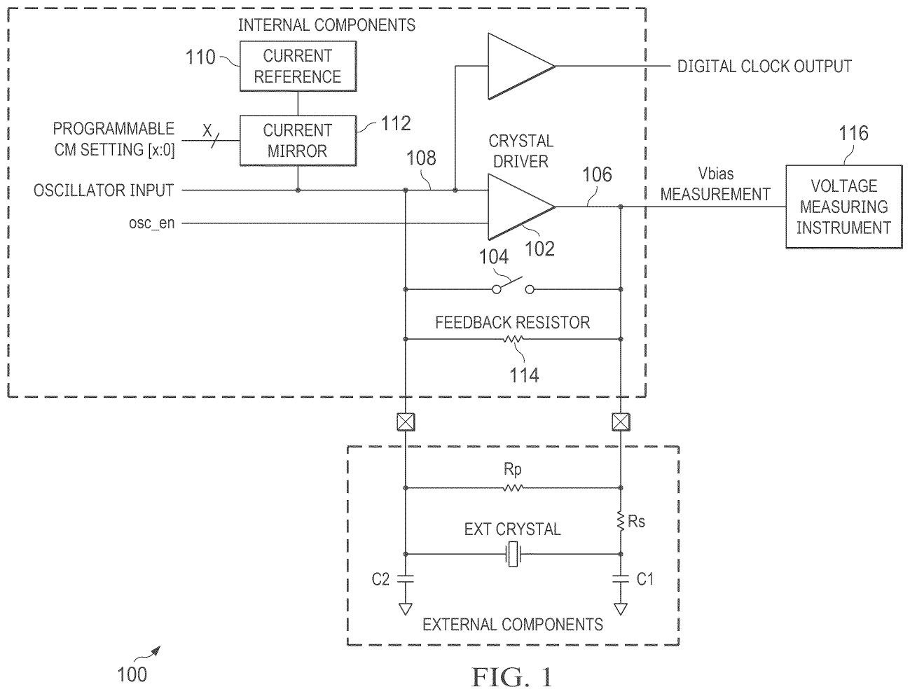

FIG. 1 shows a block diagram of an internal crystal driver gain margin measurement test circuit 100 having a programmable current mirror. A crystal driver 102 has an driver input 108 and an driver output 106. A feedback switch 104 is in parallel with a feedback resistor 114 and provides a short of the driver input 108 and the driver output 106 of the crystal driver 102, i.e. when feedback switch 104 is closed, a short circuit is presented across feedback resistor 114, and the driver output 106 is directly connected to the driver input 108. An internal current reference 110 provides a current bias as an input to a current mirror 112. The current mirror 112 provides the current bias as input to the driver input 108 of the crystal driver 102. The current mirror 112 is programmable to adjust the current bias it generates relative to the current of the internal current reference 110. When the feedback switch 104 is closed, the generated current bias from the current mirror 112 is forced on the crystal driver 102, and is sunk, or sourced, by the output of crystal driver 102. A voltage measuring instrument 116 measures the voltage (Vbias) at the driver output 106.

The crystal driver 102 may be implemented as an operational amplifier, a transconductance amplifier, or an inverting amplifier, without limitation. In FIG. 1, internal components are identified as including crystal driver 102, feedback resistor 114, feedback switch 104, current mirror 112, and current reference 110. As shown in FIG. 1, external components may include an external crystal, resistors Rs and Rp, and capacitors C1 and C2, and may represent circuit elements added in a user implementation. The internal crystal driver gain margin measurement test circuit 100 is to test that sufficient gain margin is provided by crystal driver 102 so as to successfully energize the external crystal within allowed margins for the external components.

Aspects utilize the internally based current reference (e.g., current reference 110 in combination with programmable current mirror 112) with external high precision voltage measuring provided by voltage measuring instrument 116. The circuit utilizes feedback switch 104 to provide a first current bias (I1) to measure a quiescent voltage bias point (Vbias1) with a second current bias (I2) to provide the measurement for the second voltage bias point (Vbias2). The first and second current bias (I1, I2) may be provided by current mirror 112. The error on voltage measurements may be reduced by external high precision instruments and the error on current force may be reduced by using the internal current reference 110 and the internal programmable current mirror 112. Vbias may be the operating point of the crystal driver 102 with the input terminals short circuited with zero current (i.e. I=0). This may be a “center point” of the linear region and may provide guidance of where to operate. Vbias is to be measured externally with instrumentation. Vbias may be referred to as an output because a current controlled gate is being used to measure externally the voltage differential with instrumentation. A first and a second current, with the first current being positive and the second current being negative, may be applied with the programmable current mirror 112 to obtain a first and a second measurement point for the gain margin calculation. The short circuit provided by the feedback switch may provide measurement of bias voltage (Vbias1, Vbias2) without additional board level jumper/relay or instruments forcing mismatch.

As shown in FIG. 1, when the feedback switch 104 is closed, the circuit 100 may utilize the programmable current mirror 112 to force a first current bias (I1) on the driver input 108 to measure a first quiescent voltage bias point (Vbias1) with a voltage measuring instrument 116. The circuit 100 may utilize the programmable current mirror 112 to force a second current bias (I2) on the driver input 108 to measure a second quiescent voltage bias point (Vbias2) with the voltage measuring instrument 116. The gain margin may then be determined as (I1−I2)/(Vbias1−Vbias2). For example, the gain margin may be measured via a current mode as follows.

$$Short the input to output . \qquad a$$

$$Force I 1 and measure Vbias 1 ( the input current = 6 mA , Vbias 1 = 1.04 V ) . \qquad b$$

$$Force I 2 and measure Vbias 2 ( the input current = - 6 mA , Vbias 2 = 0.96 V ) . \qquad c$$

$$GM = ( I 1 - I 2 ) / ( Vbias 1 - Vbias 2 ) = 12 mA / 80 mV = 0.15 . \qquad d$$

In this example, the voltage measurement instrument is assumed to have an accuracy of +/−100 uV, so that the worst case gain margin error due to voltage measurement is (I1−I2)/79.8 mV=0.1504. Thus, for this example, the gain margin error due to forcing is 0.25%.

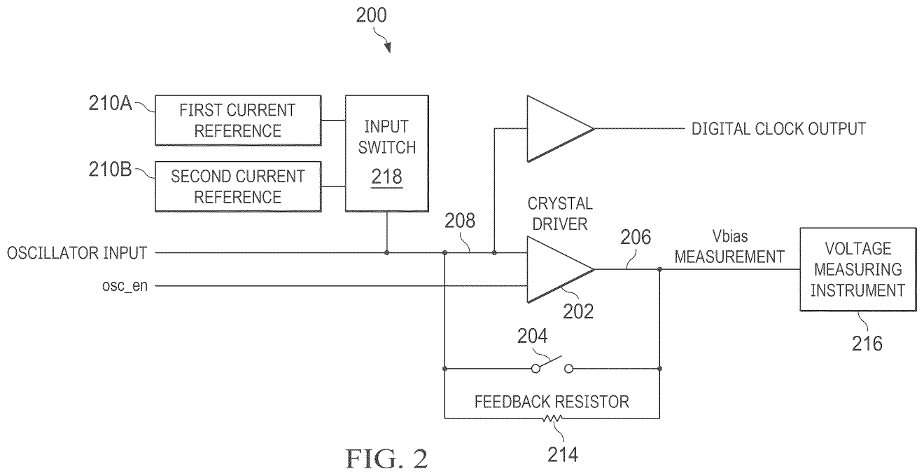

FIG. 2 shows a block diagram of an internal crystal driver gain margin measurement test circuit 200 arranged to switch between multiple current references. An crystal driver 202 has an driver input 208 and an output 206. A feedback switch 204 is in parallel with a feedback resistor 214 and provides a short of the driver input 208 to the driver output 206 of the crystal driver 202, by providing, when feedback switch 204 is closed, a short circuit across feedback resistor 214. A first current reference 210A and a second current reference 210B provide respective currents to an input switch 218. When the input switch 218 outputs the first current reference (I1) to the driver input 208, a first voltage bias point (Vbias1) may be measured by the voltage measuring instrument 216. When the input switch 218 outputs the second current reference (I2) to the driver input 208, a second voltage bias point (Vbias2) may be measured by the voltage measuring instrument 216. The gain margin may then be determined as (I1−I2)/(Vbias1−Vbias2). Input switch 218 may comprise a logic circuit to control first current reference 210A and second current reference 210B to alternately provide current, and may be implemented as a wired OR circuit in combination with the logic circuit.

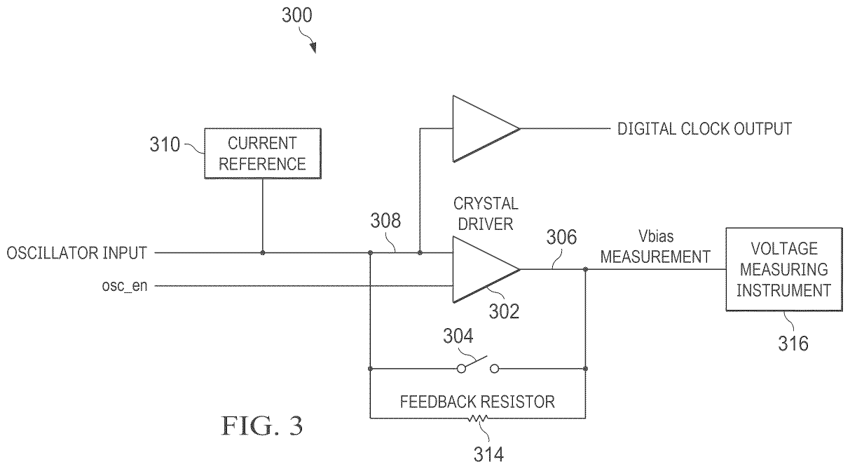

FIG. 3 shows a block diagram of an internal crystal driver gain margin measurement test circuit 300 having a current reference and a feedback switch. A crystal driver 302 has a driver input 308 and an driver output 306. A feedback switch 304 is in parallel with a feedback resistor 314 and provides a short of the driver input 308 to the driver output 306 of the driver 302 by providing, when feedback switch 304 is closed, a short circuit across feedback resistor 314. The circuit 300 may close feedback switch 304, and disable current reference 310, so as to provide a zero current bias (I1) to measure a first quiescent voltage bias point (Vbias1) with a voltage measuring instrument 316. The circuit 300 may, with feedback switch 304 closed, enable current reference 310 to provide a reference current from current reference 310 (I2) to provide the measurement for the second voltage bias point (Vbias2), which may be measured by the voltage measuring instrument 316. The gain margin may then be determined as (I1−I2)/(Vbias1−Vbias2), i.e. −I2/(Vbias1−Vbias2).

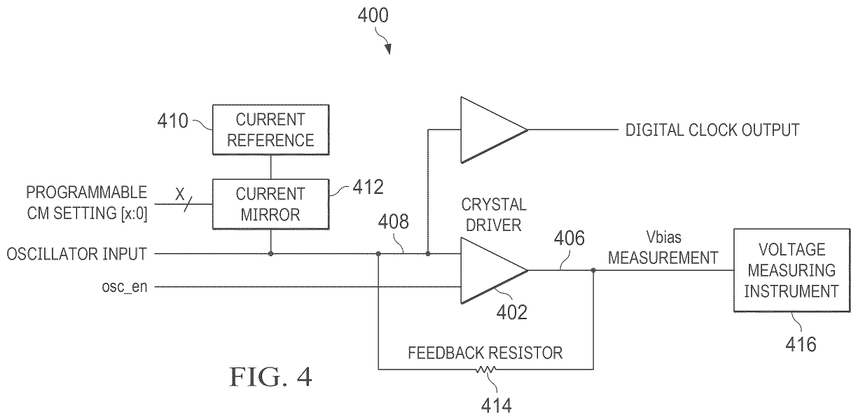

FIG. 4 shows a block diagram of an internal crystal driver gain margin measurement test circuit 400 with a programmable current mirror. A crystal driver 402 has a driver input 408 and an driver output 406. An internal current reference 410 provides a current bias as input to a current mirror 412. The current mirror 412 provides input to the driver input 408 of the crystal driver 402. The current mirror 412 is programmable to adjust the current it generates relative to the current of the internal current reference 410. The circuit 400 may utilize the programmable current mirror 412 to force a first current bias (I1) on the driver input 408 to measure a first quiescent voltage bias point (Vbias1) with a voltage measuring instrument 416. The circuit 400 may utilize the programmable current mirror 412 to force a second current bias (I2) on the driver input 408 to measure a second quiescent voltage bias point (Vbias2) with the voltage measuring instrument 416. The gain margin may then be determined as (I1−I2)/(Vbias1−Vbias2).

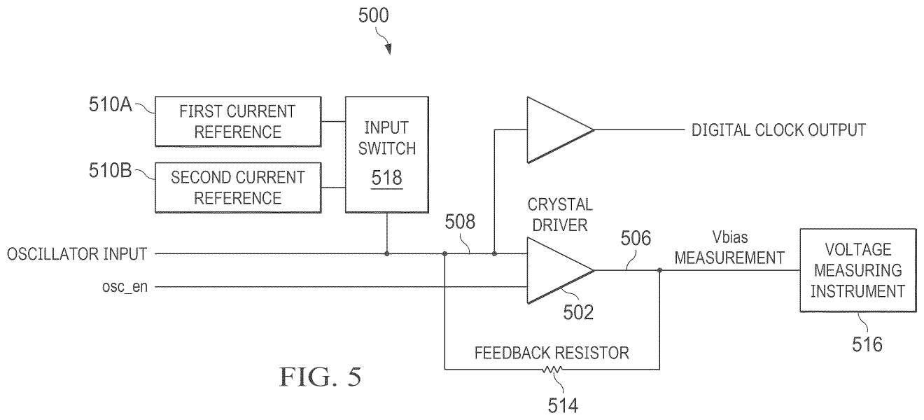

FIG. 5 shows a block diagram of an internal crystal driver gain margin measurement test circuit 500 has two current references. A crystal driver 502 has an driver input 508 and an driver output 506. A first current reference 510A and a second current reference 510B provide respective currents to an input switch 518. When the input switch 518 outputs the first current reference (I1) to the driver input 508, a first quiescent voltage bias point (Vbias1) may be measured by the voltage measuring instrument 516. When the input switch 518 outputs the second current reference (I1) to the driver input 508, a second quiescent voltage bias point (Vbias2) may be measured by the voltage measuring instrument 516. The gain margin may then be determined as (I1−I2)/(Vbias1−Vbias2). Input switch 518 may comprise a logic circuit to control first current reference 510A and second current reference 510B to alternately provide current, and may be implemented as a wired OR circuit in combination with the logic circuit.

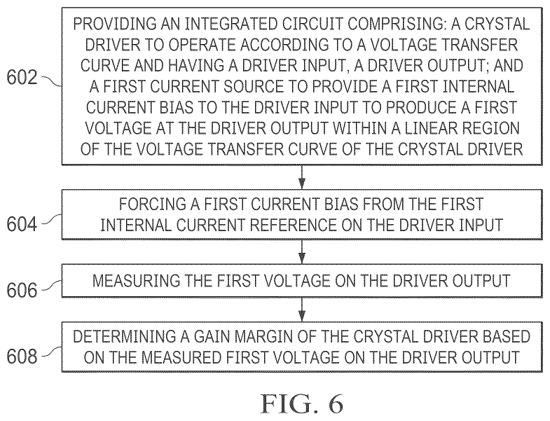

FIG. 6 shows a flow chart of a method. A device, such as an integrated circuit is provided 602 comprising: a crystal driver to operate according to a voltage transfer curve and having a driver input, and a driver output; and a first current reference to provide a first current bias to the driver input to produce a first voltage at the driver output within a linear region of the voltage transfer curve of the crystal driver. A first current bias from the first internal current reference is forced 604 on the driver input. The first voltage on the driver output is measured 606. A gain margin of the crystal driver is determined 608 based on the measured first voltage on the driver output.

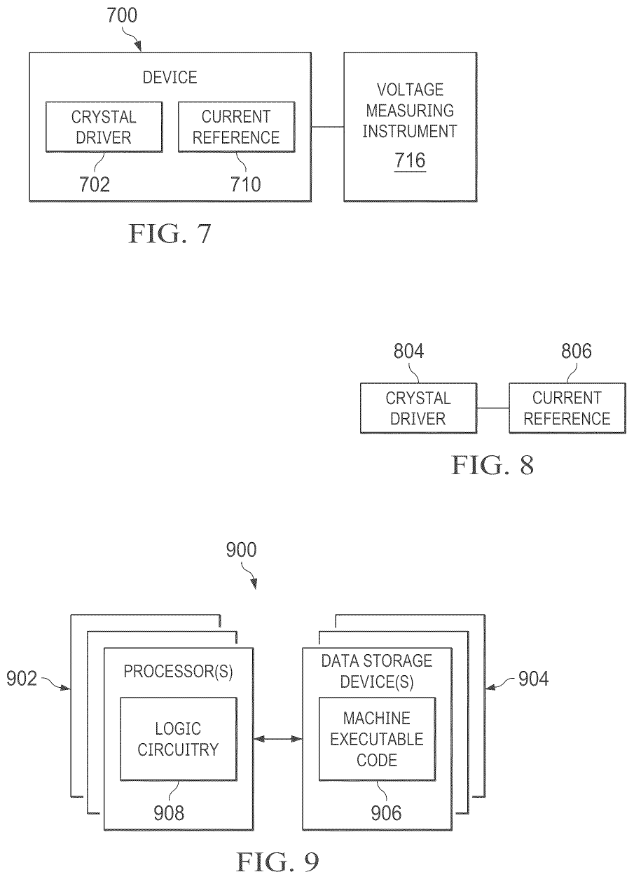

FIG. 7 shows a block diagram of a system. A device 700, such as an integrated circuit, has a crystal driver 702 to operate according to a voltage transfer curve and having an driver input, and an driver output, and first current reference 710 to provide a first current bias to the driver input to produce a first voltage at the driver output within a linear region of the voltage transfer curve of the crystal driver. A voltage measuring instrument 716 communicates with the device such as an integrated circuit 702 to measure the first voltage on the driver output when the first current bias is forced on the driver input.

FIG. 8 shows a block diagram of device, such as an integrated circuit. The integrated circuit has a crystal driver 804 to operate according to a voltage transfer curve and having an driver input, and an driver output, and a first current reference 806 to provide a first current bias to the driver input to produce a first voltage at the driver output within a linear region of the voltage transfer curve of the crystal driver.

FIG. 9 is a block diagram of circuitry 900 that, in some aspects, may be used to implement various functions, operations, acts, processes, and/or methods disclosed herein. The circuitry 900 includes one or more processors 902 (sometimes referred to herein as “processors 902”) operably coupled to one or more data storage devices (sometimes referred to herein as “storage 904”). The storage 904 includes machine executable code 906 stored thereon and the processors 902 include logic circuitry 908. The machine executable code 906 includes information describing functional elements that may be implemented by (e.g., performed by) the logic circuitry 908. The logic circuitry 908 is adapted to implement (e.g., perform) the functional elements described by the machine executable code 906. The circuitry 900, when executing the functional elements described by the machine executable code 906, may be considered as specific purpose hardware configured for carrying out functional elements disclosed herein. In some aspects the processors 902 may perform the functional elements described by the machine executable code 906 sequentially, concurrently (e.g., on one or more different hardware platforms, or in one or more parallel process streams.

When implemented by logic circuitry 908 of the processors 902, the machine executable code 906 adapts the processors 902 to perform operations of aspects disclosed herein. For example, the machine executable code 906 may adapt the processors 902 to perform at least a portion or a totality of the method of FIG. 6. As another example, the machine executable code 906 may adapt the processors 902 to perform at least a portion or a totality of the operations discussed for the device 700 of FIG. 7 and the device shown in FIG. 8. As a specific, non-limiting example, the machine executable code 906 may adapt the processors 902 to perform at least a portion of the gain margin determination discussed herein.

The processors 902 may include a general purpose processor, a specific purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein, A general-purpose computer including a processor is considered a specific-purpose computer while the general-purpose computer is configured to execute functional elements corresponding to the machine executable code 906 (e.g., software code, firmware code, hardware descriptions) related to aspects of the present disclosure. It is noted that a general-purpose processor (may also be referred to herein as a host processor or simply a host) may be a microprocessor, but in the alternative, the processors 902 may include any conventional processor, controller, microcontroller, or state machine. The processors 902 may also be implemented as a combination of computing devices, such as a combination of a DSP and a microprocessor, a plurality of microprocessors, one or more microprocessors in conjunction with a DSP core, or any other such configuration.

In some aspects the storage 904 includes volatile data storage (e.g., random-access memory (RAM)), non-volatile data storage (e.g., Flash memory, a hard disc drive, a solid state drive, erasable programmable read-only memory (EPROM), without limitation). In some aspects the processors 902 and the storage 904 may be implemented into a single device (e.g., a semiconductor device product, a system on chip (SOC), without limitation). In some aspects the processors 902 and the storage 904 may be implemented into separate devices.

In some aspects the machine executable code 906 may include computer-readable instructions (e.g., software code, firmware code), By way of non-limiting example, the computer-readable instructions may be stored by the storage 904, accessed directly by the processors 902, and executed by the processors 902 using at least the logic circuitry 908. Also by way of non-limiting example, the computer-readable instructions may be stored on the storage 904, transferred to a memory device (not shown) for execution, and executed by the processors 902 using at least the logic circuitry 908, Accordingly, in some aspects the logic circuitry 908 includes electrically configurable logic circuitry 908.

In some aspects the machine executable code 906 may describe hardware (e.g., circuitry) to be implemented in the logic Circuitry 908 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog™, SysteinVerilog™ or very large scale integration (VLSI hardware description language (VHDL™) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuitry 908 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some aspects, the machine executable code 906 may include an HDL, an RTL, a GL description, a mask level description, other hardware description, or any combination thereof.

In aspects where the machine executable code 906 includes a hardware description (at any level of abstraction), a system (not shown, but including the storage 904) may be configured to implement the hardware description described by the machine executable code 906. By way of non-limiting example, the processors 902 may include a programmable logic device (e.g., FPGA or a PLC) and the logic circuitry 908 may be electrically controlled to implement circuitry corresponding to the hardware description into the logic circuitry 908, Also, by way of non-limiting example, the logic circuitry 908 may include hard-wired logic manufactured by a manufacturing system (not shown, but including the storage 904) according to the hardware description of the machine executable code 906.

Regardless of whether the machine executable code 906 includes computer-readable instructions or a hardware description, the logic circuitry 908 is adapted to perform the functional elements described by the machine executable code 906 when implementing the functional elements of the machine executable code 906. It is noted that although a hardware description may not directly describe functional elements, a hardware description indirectly describes functional elements that the hardware elements described by the hardware description are capable of performing.

Although examples have been described above, other variations and examples may be made from this disclosure without departing from the spirit and scope of these disclosed examples.

1. A method comprising:
providing a device comprising:
a crystal driver to operate according to a voltage transfer curve and having a driver input and a driver output; and
a first current reference to provide a first current bias to the driver input to produce a first voltage at the driver output within a linear region of the voltage transfer curve of the crystal driver;
forcing the first current bias from the first current bias on the driver input;
measuring the first voltage on the driver output; and
determining a gain margin of the crystal driver based on the measured first voltage on the driver output.

2. The method as in claim 1, comprising:
shorting the driver output to the driver input while forcing the first current bias from the first internal current reference on the driver input;
measuring a second voltage on the driver output; and
determining a gain margin of the crystal driver based on the measured first and second voltages on the driver output.

3. The method as in claim 1, wherein the provided the device comprises:
a second current reference to provide a second current bias to the driver input to produce a second voltage at the driver output within a linear region of the voltage transfer curve of the crystal driver; and
an input switch to switch between the first current bias and the second current bias;
the method comprising:
forcing the second current bias on the driver input;
measuring a second voltage on the driver output; and
determining the gain margin of the crystal driver based on the measured first and second voltages on the driver output.

4. The method as in claim 1,
wherein the provided device comprises:
a programmable current mirror to provide the first current bias from the first current reference to the driver input and to provide a second current bias from the first current reference to the driver input, wherein the first and second current biases are to produce a first voltage and a second voltage at the driver output, respectively, that are within the linear region of the voltage transfer curve of the crystal driver;
the method comprising:
forcing the second current bias on the driver input;
measuring the second voltage on the driver output; and
determining the gain margin of the crystal driver based on the measured first and second voltages on the driver output.

5. The method as in claim 1, wherein measuring the first voltage on the driver output comprises measuring with an external voltage instrument having an accuracy of +/−100 μV.

6. The method as in claim 1, comprising measuring a second voltage on the driver output, wherein determining the gain margin of the crystal driver is based on the measured first and second voltages on the driver output.

7. The method as in claim 1, comprising
forcing a zero bias current on the driver input;
measuring a second voltage on the driver output; and
determining a gain margin of the crystal driver by dividing a difference between the first current bias and zero current bias by a difference between the first and second voltages.

8. The method as in claim 1, comprising
forcing a second current bias on the driver input;
measuring a second voltage on the driver output; and
determining the gain margin of the crystal driver by dividing the difference between the first and second current biases by the difference between the first and second voltages.

9. A device comprising:
a crystal driver to operate according to a voltage transfer curve and having an driver input, and an driver output; and
a first current reference to provide a first current bias to the driver input to produce a first voltage at the driver output within a linear region of the voltage transfer curve of the crystal driver.

10. The device as in claim 9, comprising a feedback switch to short the driver output to the driver input to provide a zero current bias to the driver input when the feedback switch is closed.

11. The device as in claim 9, comprising:
a second current reference to provide a second current bias to the driver input to produce a second voltage at the driver output within a linear region of the voltage transfer curve of the crystal driver; and
an input switch to switch between the first current bias and the second current bias.

12. The device as in claim 9, comprising a programmable current mirror to provide the first current bias from the first current reference to the driver input and to provide a second current bias from the first current reference to the driver input, wherein the first and second current biases are to produce the first voltage and a second voltage at the driver output, respectively, that are within a linear region of the voltage transfer curve of the crystal driver.

13. A system comprising:
a device comprising:
a crystal driver to operate according to a voltage transfer curve and having an driver input, and an driver output; and
a first current reference to provide a first current bias to the driver input to produce a first voltage at the driver output within a linear region of the voltage transfer curve of the crystal driver; and
a voltage measuring instrument to measure the first voltage on the driver output when the first current bias is forced on the driver input.

14. The system as in claim 13, wherein the device comprises a feedback switch to short the driver output to the driver input to provide a zero current bias to the driver input when the feedback switch is closed to produce a second voltage on the driver output.

15. The system as in claim 14, wherein the voltage measuring instrument is to measure the second voltage at the driver output when the zero current bias is provided on the driver input.

16. The system as in claim 13, wherein the device comprises:
a second current reference to provide a second current bias to the driver input to produce a second voltage at the driver output within a linear region of the voltage transfer curve of the crystal driver; and
an input switch to switch between the first current bias and the second current bias.

17. The system as in claim 16, wherein the voltage measuring instrument is to measure the second voltage at the driver output when the second current bias is provided to the driver input.

18. The system as in claim 13, wherein the device comprises a programmable current mirror to provide the first current bias from the first current reference to the driver input and to provide a second current bias from the first current reference to the driver input, wherein the first and second current biases are to produce the first voltage and a second voltage at the driver output, respectively, that are within a linear region of the voltage transfer curve of the crystal driver.

19. The system as in claim 18, wherein the voltage measuring instrument is to measure the second voltage at the driver output when the second current bias is provided to the driver input.

20. The system as in claim 13, wherein the voltage measuring instrument has an accuracy of +/−100 μV.
